(19) United States
(12) Patent Application Publication
(10) Pub. No.: US 2006/0102891 A1
(43) Pub. Date: May 18, 2006

(54) Organic photovoltaic component and method for production thereof

(76) Inventors: Christoph Brabec, Linz (DE); Jens Hauch, Erlangen (DE)

Correspondence Address: FISH & RICHARDSON PC, P.O. BOX 1022, MINNEAPOLIS, MN, 55440-1022, US

(21) Appl. No.: 10/525,058

(22) PCT Filed: Sep. 3, 2003
(86) PCT No.: PCT/DE03/02930

§ 371 Date: Sep. 6, 2005

(30) Foreign Application Priority Data
Sep. 5, 2002 (DE) 102 41 204.9

(51) Int. Cl. H01L 29/08

(52) U.S. Cl. 257/40

(57) ABSTRACT

The invention relates to an organic photovoltaic component, in particular an organic solar cell, in which one or more layers is (are) structured.

The invention relates to an organic photovoltaic component, particularly an organic solar cell.

Solar cells having the following cell structure, for example, are known:

Disposed on a substrate is a positive electrode (typically ITO, indium tin oxide). On top of that is the hole-conducting layer, composed for example of PEDOT with PSS as the anion. The next layer is an absorber, usually an organic semiconductor (e.g. a mixture of conjugated polymer with fullerene). This is followed by the negative electrode (e.g. Ca/Ag or LiF/Al). The individual layers can differ from this scheme, however, especially the electrodes, the conjugated polymer and also the acceptor (PCBM, a soluble methanofullerene).

Due to the very low mobility of the semiconductors typically used in these solar cells, the active semiconductor layer (the absorber) is made very thin (typically between 20 nm and 2000 nm) to prevent recombination. However, this thin absorber layer usually is not sufficient to fully absorb the incoming light. Some of the light is therefore lost (absorbed) at the back electrode or reflected there (and coupled out again through the front of the solar cell).

The object of the invention is, therefore, to reduce these loss processes by means of a process step that is as simple and inexpensive as possible.

The invention is directed to an organic photovoltaic component comprising a substrate, a positive electrode, an organic semiconductor and a negative electrode, wherein the substrate and/or one or more additional transport layer(s) between the electrode and the semiconductor layer is (are) structured. The invention is also directed to a method for structuring the semiconductor layer of a photovoltaic component by preserving an existing structure of a lower layer to which the semiconductor layer is applied.

In one embodiment of the invention, the substrate is structured and the electrode and the semiconductor layer therefore follow the structuring, and the absorptivity of the semiconductor layer is thereby increased.

In another embodiment, the semiconductor layer is applied in such a way that it planarizes the structure.

In one embodiment, plural layers beneath the semiconductor layer are structured. Intermediate layers can also be built into the photovoltaic component to create a structured surface to which the semiconductor layer is applied.

Structuring one or more layers of the photovoltaic element improves the coupling of light into the solar cell. This kind of structuring is therefore also known as “light trapping.”

The terms “organic material” and/or “functional polymer” herein encompass all types of organic, metalorganic and/or organic/inorganic synthetics, denoted in English, for example, by “plastics.” This includes all types of materials except for the semiconductors that form conventional diodes (germanium, silicon) and typical metallic conductors. Hence, there is no intended limitation in the dogmatic sense to organic material as carbon-containing material, but rather, the broadest use of silicones, for example, is also contemplated. Furthermore, the terms are not intended to be subject to any limitation with respect to molecular size, particularly to polymeric and/or oligomeric materials, but instead the use of “small molecules” is completely feasible as well.

Light trapping is generally achieved by imparting a periodic structure to at least one of the layers of the solar cell. It has, in fact, already been proposed (M. Niggeman et al., “Trapping light in organic plastic solar cells with integrated diffraction gratings,” Proceedings of the World Photovoltaic Congress, Munich 2001) to structure the absorber periodically (for example by means of an embossing or stamping process). Embossing the semiconductor, however, is a critical process step, since the sensitive semiconductor layer can easily become damaged during this process. This notwithstanding, the structuring of the semiconductor layer can be performed in the sense of the invention in combination with the structuring of the substrate and/or of an additional transport layer.

The terms the upper layer “follows the structure” and/or “reproduces the structure upwardly” merely describes [sic] the fact that at least some of the lower structure is traced upwardly, i.e., the lower structure is duplicated in part or in whole on top. The upper structure can also undergo additions to the structuring, so that a completely different structure is formed. The invention is not intended to be limited in any way in this regard.

The invention is described in more detail below on the basis of individual examples relating to embodiments of the invention.

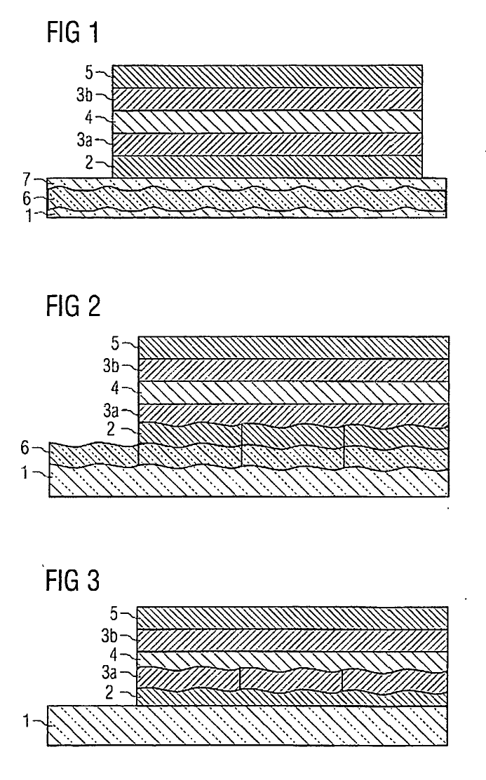

FIG. 1 shows a layer structure of a photovoltaic component in which the substrate is structured and is replanarized by an additional transport layer, and the bottom electrode then already goes back to being applied to a planar surface.

FIG. 2 shows a photovoltaic component in which an additional matching layer for adapting the optical properties is applied to the substrate in such a way that the structure is reproduced upwardly and effects a structuring of the electrode layer, which is then planarized by a hole-conducting layer, so that the semiconductor layer is applied to a planar surface.

FIG. 3 shows a photovoltaic component in which a bottom electrode is structured on a planar substrate, the structure works its way through a hole-conducting layer, and finally the semiconductor layer is applied to a structured surface.

In FIG. 1, the substrate, identified as 1, can be a PET sheet or a layer of photoresist on glass. This substrate is structured and is coated with an additional layer 6, for example of a material having a high refractive index, such as TiO₂, so that the structure is traced, and is then replanarized by a layer 7 of a transparent material that can also be a PET sheet or a layer of photoresist on glass. The standard cell is then processed on this substrate from the bottom up, as, first, a bottom electrode 2, which is implemented as semitransparent (e.g. of ITO) for the case in which the side on which substrate 1 is located is the light-incident side of the photovoltaic component. Disposed thereon in this embodiment is an additional organic electrode 3a, for example of PEDOT, and thereon the semiconductor layer 4 and a second electrode 3b and/or 5.

FIG. 2 illustrates a substrate 1 that is structured and to which is applied a layer 6 of a material for example having a high refractive index, which follows the structure. Disposed thereon is the bottom electrode 2, and on that an additional electrode or transport layer 3a that planarizes the structure. The semiconductor layer 4 is applied to a planar surface. The further structure includes an additional electrode or transport layer 3b and top electrode 5.

The material of layer 6 is generally a layer intended to provide improved optical properties and/or optical matching, such as, for example, a layer having a high refractive index.

FIG. 3 depicts a substrate 1 that is not structured, to which is applied a bottom electrode 2 that is structured, to which is applied an additional layer 3a that follows the structure, and to whose structured surface semiconductor layer 4 is applied. Semiconductor layer 4 planarizes the structure, so that an additional electrode 3b is applied to a planar surface of semiconductor layer 4. A further electrode 3b and top electrode 5 are not structured in the illustrated embodiment.

For the case in which the bottom electrode is not on the light-incident side, this electrode can also be made of a completely reflective material.

The invention shows, for the first time, photovoltaic components whose absorptivity of light is increased by structuring one or more layers of the component, thereby improving coupling-in. The structuring of the layers is performed without any mechanical or thermal stressing of the semiconductor layer, which therefore remains undamaged.

The invention proposes, instead of structuring the semiconductor layer, which causes an increase in absorptivity but stresses the semiconductor layer mechanically, chemically and/or physically, to structure the substrate before applying the positive or negative electrode and/or to structure an organic transport layer (e.g. PEDOT) before applying the semiconductor layer. The structuring steps involve the substrate, one of the electrodes and/or one of the additional transport layer(s), but not the semiconductor, which therefore remains unstressed.

Examples of structurable substrates would be sheets or layers of conventional polymers such as PET, PMMA, PC. These sheets can typically have a layer thickness of between 10 and 1000 microns; the depth and period of the embossed periodic structure can be in the 10-1000 nm range; the depth of aperiodic irregular embossed structures can be in the 1-500 micron range.

Examples of planarizing layers having a high optical refractive index would be polyimides and/or inorganic-nanoparticle-(TiO₂)-filled polymers.

1. An organic photovoltaic component comprising a substrate, a positive electrode, an organic semiconductor and a negative electrode, wherein said substrate and/or one or more additional transport layer(s) between said electrode and said semiconductor layer is (are) structured.

2. The organic photovoltaic component as defined in claim 1, wherein said substrate is a flexible sheet that is structured.

3. The organic photovoltaic component of claim 1, wherein said substrate and/or an additional layer above or below said semiconductor layer is structured.

4. A method for structuring the semiconductor layer of a photovoltaic component by preserving an existing structure of a lower layer to which said semiconductor layer is applied.

5. The method as defined in claim 4, wherein said semiconductor layer planarizes the structure of said lower layer(s).

6. The method as defined in claim 4, wherein said structuring is effected by introducing an additional layer.

7. A photovoltaic cell, comprising:
a substrate;
a first electrode supported by the substrate;
a second electrode;
an organic semiconductor between the positive and negative electrodes,
wherein the substrate is structured.

8. The photovoltaic cell of claim 7, wherein the substrate is flexible.

9. The photovoltaic cell of claim 7, wherein the first electrode is structured.

10. The photovoltaic cell of claim 9, wherein the first electrode is disposed on the substrate.

11. The photovoltaic cell of claim 9, wherein the first electrode is a cathode.

12. The photovoltaic cell of claim 7, further comprising a planarized layer between the substrate and the first electrode.

13. The photovoltaic cell of claim 12, wherein the first electrode is disposed on the substrate.

14. The photovoltaic cell of claim 7, further comprising a planarized layer between the organic semiconductor and the first electrode.

15. The photovoltaic cell of claim 14, wherein the first electrode is disposed on the substrate.

16. A photovoltaic cell, comprising:
a substrate;
a first electrode supported by the substrate;
a second electrode;
an organic semiconductor between the positive and negative electrodes,
wherein the first electrode is structured.

17. The photovoltaic cell of claim 16, wherein the substrate is not structured.

18. The photovoltaic cell of claim 16, further comprising a first layer supported by the first electrode, the additional layer being structured.

19. The photovoltaic cell of claim 18, further comprising a second layer supported by the first layer, the second layer being planarized.

20. The photovoltaic cell of claim 16, wherein the substrate is flexible.
